(19) United States
(12) Patent Application Publication
(10) Pub. No.: US 2026/0361305 A1
(43) Pub. Date: Nov. 12, 2026

(54) SEMICONDUCTOR RELAY

(71) Applicant: Panasonic Intellectual Property Management Co., Ltd., Osaka (JP)

(72) Inventors: Kazuaki YOSHIOKA, Mie (JP); Yasushi KONISHI, Osaka (JP)

(21) Appl. No.: 19/126,104

(22) PCT Filed: Oct. 13, 2023
(86) PCT No.: PCT/JP2023/037232

§ 371 Date: Apr. 30, 2025

Related U.S. Application Data
(60) Provisional application No. 63/427,295, filed on Nov. 22, 2022.

(51) Int. Cl. H03K 17/691; H10D 30/63

(52) U.S. Cl. CPC H03K 17/691; H10D 30/63

(57) ABSTRACT

A semiconductor relay includes an oscillation circuit, an inductor, a rectifier circuit, a voltage stabilization circuit, a charging/discharging circuit, and a first MOSFET. The oscillation circuit outputs a first signal. The inductor amplifies the first signal and outputs the amplified signal as a second signal. The rectifier circuit rectifies the second signal and outputs the rectified signal as a third signal. The voltage stabilization circuit stabilizes the voltage of the third signal and outputs the stabilized signal as a fourth signal. The charging/discharging circuit charges the gate of the first MOSFET with the fourth signal or discharges the gate through the fourth signal. The inductor has: a first inductor that receives the inputted first signal; and a second inductor that outputs the second signal.

### TECHNICAL FIELD

The present disclosure relates to a semiconductor relay, and particularly to a magnetically coupled semiconductor relay.

### BACKGROUND ART

There have been conventionally known semiconductor relays that use magnetic coupling between inductors to perform a switching operation in response to an input signal and transmit signals (see, for example, Patent Document 1).

### CITATION LIST

### Patent Document

PATENT DOCUMENT 1: Japanese Unexamined Patent Publication No. 2022-070567

### SUMMARY OF THE INVENTION

### Technical Problem

However, in such a magnetically coupled semiconductor relay, the output voltage of an inductor may fluctuate due to a load or the like connected to a semiconductor switch included in an output unit. If the output voltage of the inductor exceeds an overvoltage threshold due to such fluctuations, problems may occur: the semiconductor switch that operates upon receiving the output voltage may fail or become unstable, for example.

The present disclosure has been made in view of such circumstances, and an object thereof is to provide a magnetically coupled semiconductor relay that stabilizes the output voltage of an inductor and has enhanced operational reliability.

### Solution to the Problem

To achieve the foregoing object, a semiconductor relay related to the present disclosure includes: an oscillation circuit configured to output a first signal; an inductor configured to amplify the first signal inputted from the oscillation circuit and output the amplified signal as a second signal; a rectifier circuit configured to rectify the second signal inputted from the inductor and output the rectified signal as a third signal; a voltage stabilization circuit configured to stabilize a voltage of the third signal and output the stabilized signal as a fourth signal; a charging/discharging circuit configured to perform charging and discharging through the fourth signal; and a first MOSFET configured to receive the fourth signal inputted thereto, and the inductor includes: a first inductor configured to receive the first signal inputted from the oscillation circuit; and a second inductor configured to output the second signal to the rectifier circuit.

### Advantages of the Invention

The present disclosure is advantageous in that even if an excessive voltage is generated in the inductor, it is possible to reduce the likelihood of the first MOSFET failing due to the excessive voltage inputted to an output circuit. Furthermore, it is possible to stabilize the operation of the first MOSFET. It is consequently possible to enhance the operational reliability of the semiconductor relay.

### BRIEF DESCRIPTION OF THE DRAWINGS

FIG. 1 is a functional block diagram of a semiconductor relay related to a first embodiment.

FIG. 2 is a circuit diagram of the semiconductor relay.

FIG. 3A is a schematic sectional view of an example of a first MOSFET.

FIG. 3B is a schematic sectional view of another example of the first MOSFET.

FIG. 4A is a schematic diagram showing a set of substrates that can be mounted on the semiconductor relay.

FIG. 4B is a schematic diagram showing another set of substrates that can be mounted on the semiconductor relay.

FIG. 5A is a schematic diagram showing a set of substrates that can be mounted on a semiconductor relay related to a first variation.

FIG. 5B is a schematic diagram showing another set of substrates that can be mounted on the semiconductor relay related to the first variation.

FIG. 6A is a circuit diagram of a first charging/discharging circuit related to a second variation.

FIG. 6B is a circuit diagram of a second charging/discharging circuit related to the second variation.

FIG. 6C is a circuit diagram of a third charging/discharging circuit related to the second variation.

FIG. 7 is a circuit diagram of a voltage stabilization circuit related to the second variation.

FIG. 8 is a functional block diagram of a semiconductor relay related to a second embodiment.

FIG. 9 is a schematic diagram showing a set of substrates that can be mounted on the semiconductor relay.

FIG. 10 is a functional block diagram of another semiconductor relay related to the second embodiment.

FIG. 11 is a schematic diagram showing another set of substrates that can be mounted on the semiconductor relay.

FIG. 12 is a functional block diagram of still another semiconductor relay related to the second embodiment.

FIG. 13 is a schematic diagram showing still another set of substrates that can be mounted on the semiconductor relay.

FIG. 14A is a circuit diagram of an overcurrent protection circuit.

FIG. 14B is a circuit diagram of an overheat protection circuit.

FIG. 15A is a circuit diagram of an overvoltage protection circuit.

FIG. 15B is a circuit diagram of another overvoltage protection circuit.

FIG. 16 is a functional block diagram of a semiconductor relay related to a third embodiment.

FIG. 17A is a schematic diagram showing a set of substrates that can be mounted on the semiconductor relay.

FIG. 17B is a schematic diagram showing another set of substrates that can be mounted on the semiconductor relay.

FIG. 18 is a circuit diagram of a failure detection circuit.

FIG. 19 is a functional block diagram of a semiconductor relay related to a fourth embodiment.

FIG. 20 is a circuit diagram of an undervoltage lockout circuit.

### DESCRIPTION OF EMBODIMENTS

The following describes embodiments of the present disclosure with reference to the drawings. Note that the following description of preferred embodiments is merely an example in nature, and is not intended to limit the scope, applications, or use of the present disclosure.

### First Embodiment

[configuration of Semiconductor Relay]

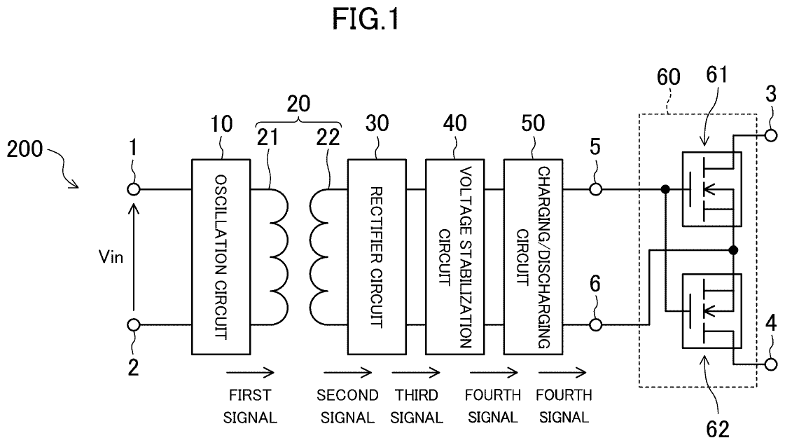

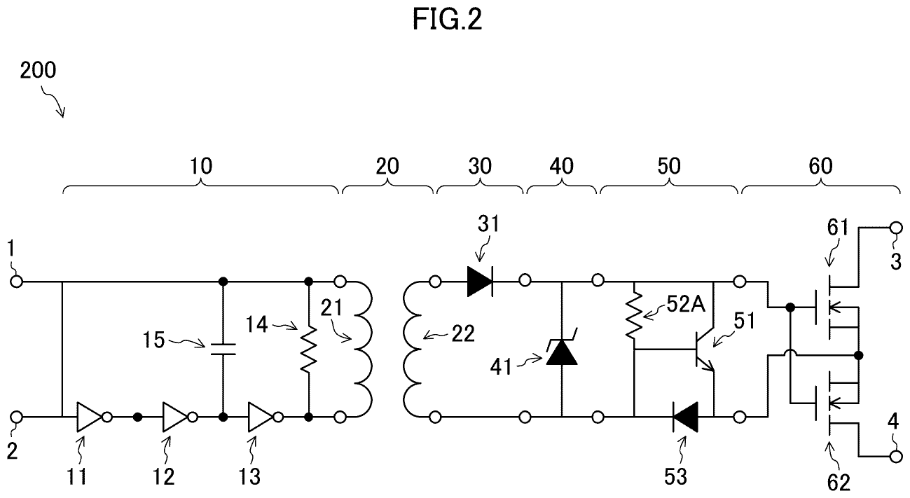

FIG. 1 is a functional block diagram of a semiconductor relay related to a first embodiment. FIG. 2 is a circuit diagram of the semiconductor relay.

As shown in FIG. 1, a semiconductor relay 200 includes first to fourth terminals 1 to 4 and fifth and sixth terminals 5 and 6. The semiconductor relay 200 further includes, as functional blocks, an oscillation circuit 10, an inductor 20, a voltage stabilization circuit 40, a rectifier circuit 30, a charging/discharging circuit 50, and an output circuit 60.

In the semiconductor relay 200, an input signal Vin is applied between the first terminal 1 and the second terminal 2, which are input terminals, and an output signal corresponding to the input signal Vin is transmitted to be applied between the third terminal 3 and the fourth terminal 4, which are output terminals. In a case where a load (not shown) is connected to the third terminal 3 and the fourth terminal 4, the output signal is transmitted to the load. As will be described later, the functional blocks of the semiconductor relay 200 may be separately provided on different substrates. In this case, the fifth and sixth terminals 5 and 6 function as input terminals for a fourth signal, which is inputted to the output circuit 60.

The oscillation circuit 10 outputs a first signal based on the input signal Vin applied between the first terminal 1 and the second terminal 2. As shown in FIG. 2, the oscillation circuit 10 has first to third inverters 11 to 13, a resistor 14, and a capacitor 15. The first to third inverters 11 to 13 are connected in series, and the capacitor 15 is connected, in parallel, to a connection point between the second inverter 12 and the third inverter 13. The resistor 14 is connected, in parallel, to the output of the third inverter 13.

As the potential at the connection point between the second inverter 12 and the third inverter 13 drops, the potential at the output point of the third inverter 13 rises. When the capacitor 15 is charged by current flowing through the resistor 14, the low potential at the connection point between the second inverter 12 and the third inverter 13 rises. Then, the charge stored in the capacitor 15 is discharged through the resistor 14, and the potential at the connection point between the second inverter 12 and the third inverter 13 drops.

These operations are periodically repeated, and an output signal from the third inverter 13 is outputted as the first signal. The configuration of the oscillation circuit 10 is not particularly limited to that shown in FIG. 2.

The inductor 20 amplifies the first signal inputted from the oscillation circuit 10 and outputs the amplified signal as a second signal. As shown in FIGS. 1 and 2, the inductor 20 is a transformer having a first inductor 21 and a second inductor 22. The first signal inputted to the first inductor 21 is outputted to the second inductor 22 magnetically coupled to the first inductor 21. At this time, the first signal is amplified at a transformation ratio corresponding to the ratio of the number of turns between the first inductor 21 and the second inductor 22, and the amplified signal is outputted to the rectifier circuit 30 as the second signal.

The rectifier circuit 30 rectifies the second signal inputted from the second inductor 22 of the inductor 20 and outputs the rectified signal as a third signal. The rectifier circuit 30 shown in FIG. 2 is configured with a diode 31; however, the rectifier circuit 30 may have another configuration.

The voltage stabilization circuit 40 stabilizes the voltage of the third signal inputted from the rectifier circuit 30 and outputs the stabilized signal as the fourth signal. The voltage stabilization circuit 40 shown in FIG. 2 includes a Zener diode 41 connected in parallel to the rectifier circuit 30, and the voltage value of the fourth signal is clamped with the Zener voltage of the Zener diode 41. The configuration of the voltage stabilization circuit 40 is not particularly limited to that shown in FIG. 2. This will be described later.

As shown in FIG. 2, the charging/discharging circuit 50 has an NPN bipolar transistor 51, a resistor 52A, and a diode 53. The resistor 52A is connected between the collector and base of the NPN bipolar transistor 51, and the diode 53 is connected between the base and emitter of the NPN bipolar transistor 51. Furthermore, the collector of the NPN bipolar transistor 51 is connected to the respective gates of a first MOSFET 61 and a second MOSFET 62, and the emitter of the NPN bipolar transistor 51 is connected to the respective sources of the first MOSFET 61 and the second MOSFET 62.

When the fourth signal is inputted from the voltage stabilization circuit 40 to the charging/discharging circuit 50, the potential at the collector of the NPN bipolar transistor 51 becomes high, while the potential at the base of the NPN bipolar transistor 51 is low. Due to this, the base-emitter voltage thereof becomes substantially zero, and the NPN bipolar transistor 51 is turned off. In this case, due to the current flowing through the resistor 52A, current flows between the gate and source of each of the first MOSFET 61 and the second MOSFET 62, and these gates are charged.

When the input of the fourth signal from the voltage stabilization circuit 40 is stopped, the charge stored in the gate of each of the first MOSFET 61 and the second MOSFET 62 is supplied to the base of the NPN bipolar transistor 51, turning on the NPN bipolar transistor 51. As the NPN bipolar transistor 51 is turned on, the charge is extracted from the gates of the first MOSFET 61 and the second MOSFET 62 through the NPN bipolar transistor 51, and these gates are discharged. The diode 53 is provided to prevent reverse current flow to the output circuit 60 during gate charging and to enhance charge extraction from the gates during gate discharging. The configuration of the charging/discharging circuit 50 is not particularly limited to the that shown in FIG. 2. This will be described later.

The output circuit 60 has the first MOSFET 61 and the second MOSFET 62. Each of the first MOSFET 61 and the second MOSFET 62 is an N-channel enhancement-mode MOSFET (hereinafter, may be referred to as an E-MOSFET). The source of the first MOSFET 61 and the source of the second MOSFET 62 are connected to each other. The drain of the first MOSFET 61 is connected to the third terminal 3, and the drain of the second MOSFET 62 is connected to the fourth terminal 4. In the following description, the first MOSFET 61 may be referred to as first semiconductor switch 61, and the second MOSFET 62 may be referred to as second semiconductor switch 62.

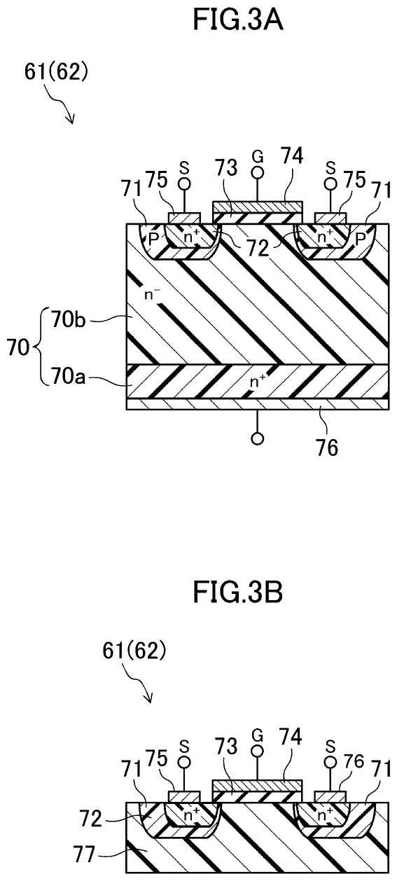

FIG. 3A is a schematic sectional view showing an example of the first MOSFET, and FIG. 3B is a schematic sectional view showing another example of the first MOSFET. In this embodiment, the first MOSFET 61 and the second MOSFET 62 have the same sectional structure. Therefore, the sectional structures shown in FIGS. 3A and 3B are also applicable to the second MOSFET 62. Furthermore, in this embodiment, the first MOSFET 61 and the second MOSFET 62 have the same input/output characteristics.

The first MOSFET 61 shown in FIG. 3A is a known vertical MOSFET. A gate electrode 74 is provided on a front surface of a substrate 70 via a gate oxide film 73. Furthermore, a p-type well 71 surrounds the gate electrode 74 when viewed from a direction orthogonal to the front surface of the substrate 70. A high-concentration n-type region 72 (n⁺ region 72) is inside the p-type well 71 on the front surface of the substrate 70. The n⁺ region 72 is a source region of the first MOSFET 61. In the example shown in FIG. 3A, a source electrode 75 is directly on a surface of the n⁺ region 72; however, in practice, the source electrode 75 is formed on a surface of an interlayer insulating film (not shown) formed on the front surface of the substrate 70. The source electrode 75 and the n⁺ region 72 are electrically connected to each other via a contact (not shown) that penetrates the interlayer insulating film.

The substrate 70 includes an n⁻ region 70a and an n⁺ region 70b provided on a back surface of the n⁻ region 70a. The n⁻ region 70a and the n⁺ region 70b form a drain region. A drain electrode 76 is on a back surface of the n⁺ region 70b. That is, the first MOSFET 61 shown in FIG. 3A is provided with: a gate terminal and a source terminal that are on the front surface of the substrate 70; and a drain terminal that is on the back surface of the substrate 70. The first MOSFET 61 shown in FIG. 3A allows the drain region to have a longer vertical length over which drain voltage is applied, enabling the first MOSFET 61 to achieve a high breakdown voltage.

The first MOSFET 61 shown in FIG. 3B is a known lateral MOSFET. The gate electrode 74 is provided on a surface of a substrate 70 via the gate oxide film 73. The substrate 70 is a p-type semiconductor substrate. On both sides of the gate electrode 74, n⁺ regions 72 are located, with the gate electrode 74 in between the n⁺ regions 72. One of the n⁺ regions serves as a source region and the other serves as a drain region. In the example shown in FIG. 3B, the source electrode 75 and the drain electrode 76 are directly on the surfaces of the n⁺ regions 72. However, in practice, the source electrode 75 and the one of the n⁺ regions 72 are electrically connected to each other, and the drain electrode 76 and the other of the n⁺ regions 72 are electrically connected to each other, via respective contacts (not shown) penetrating interlayer insulating films, as described above. That is, the first MOSFET 61 shown in FIG. 3B is provided with the gate terminal, source terminal, and drain terminal that are on the front surface of the substrate 70. The first MOSFET 61 shown in FIG. 3B has a shorter source-drain distance, which enables higher speeds. Depending on the type of the signal transmitted to be applied between the third terminal 3 and the fourth terminal 4, the structure of the first MOSFET 61 and the second MOSFET 62 can be properly selected between the structure shown in FIG. 3A and the structure shown in FIG. 3B.

The functional blocks of the semiconductor relay 200, which are shown in FIG. 1, are separately provided on different substrates. Substrates 151 to 155 and 1545 are, for example, silicon chips. The substrate 70 is a silicon single-crystal substrate. However, depending on the type of the first MOSFET 61 and the second MOSFET 62, the fourth and fifth substrates 154 and 155 and the substrate 1545 may be compound semiconductor chips. The substrate 70 may also be a compound semiconductor single-crystal substrate.

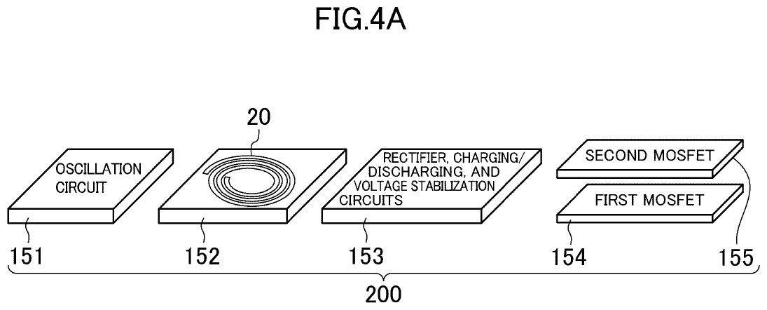

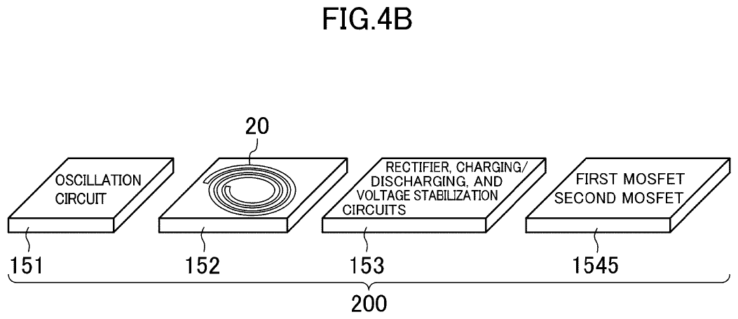

FIG. 4A is a schematic diagram showing a set of substrates that can be mounted on the semiconductor relay. FIG. 4B is a schematic diagram showing another set of substrates that can be mounted on the semiconductor relay.

As shown in FIGS. 4A and 4B, for example, the oscillation circuit 10 is provided on the first substrate 151, the inductor 20 is provided on the second substrate 152, and the rectifier circuit 30, the voltage stabilization circuit 40, and the charging/discharging circuit 50 are provided on the third substrate 153. The inductor 20 is thus provided on the substrate different from those for the other functional blocks. This can prevent electromagnetic noise from mixing with the first to fourth signals. It is also possible to increase the isolation voltage between the input and output of the semiconductor relay 200. Furthermore, as shown in FIG. 4A, the first MOSFET 61 and the second MOSFET 62 may be provided on the respective substrates different from each other, i.e., on the fourth substrate 154 and the fifth substrate 155. This makes it possible to increase the withstand voltage and current capacity of the output circuit 60. In a case where the output circuit 60 has sufficient withstand voltage and current capacity, the first MOSFET 61 and the second MOSFET 62 may be disposed on the same substrate 1545, as shown in FIG. 4B.

### [Operation of Semiconductor Relay]

The fourth signal is applied between the gate and source of the first MOSFET 61 and between the gate and source of the second MOSFET 62.

When the voltage value of the fourth signal exceeds a threshold voltage of the first MOSFET 61 and the second MOSFET 62, the first MOSFET 61 and the second MOSFET 62 are turned on, and the drain of the first MOSFET 61 and the drain of the second MOSFET 62 become conductive. The third terminal 3 is connected to the drain of the first MOSFET 61, and the fourth terminal 4 is connected to the drain of the second MOSFET 62. Accordingly, the third terminal 3 and the fourth terminal 4 become conductive to each other, allowing signal transmission between the third terminal 3 and the fourth terminal 4.

In the output circuit 60 shown in FIGS. 1 and 2, signal transmission is performed from the third terminal 3 to the fourth terminal 4 via the first MOSFET 61 and the second MOSFET 62 when the third terminal 3 is at a high potential relative to the fourth terminal 4. When the third terminal 3 is at a low potential relative to the fourth terminal 4, signal transmission is performed from the fourth terminal 4 to the third terminal 3 via the first MOSFET 61 and the second MOSFET 62.

When the voltage value of the fourth signal falls below the threshold voltage of the first MOSFET 61 and the second MOSFET 62, the first MOSFET 61 and the second MOSFET 62 are turned off, and the drain of the first MOSFET 61 and the drain of the second MOSFET 62 become non-conductive. Accordingly, the third terminal 3 and the fourth terminal 4 also become non-conductive to each other, and signal transmission between the third terminal 3 and the fourth terminal 4 is blocked.

### [Advantages]

As described above, the semiconductor relay 200 related to this embodiment includes, at least, the oscillation circuit 10, the inductor 20, the rectifier circuit 30, the voltage stabilization circuit 40, and the charging/discharging circuit 50. The semiconductor relay 200 further includes the first MOSFET 61 and the second MOSFET 62 as the output circuit 60.

The oscillation circuit 10 outputs the first signal. The inductor 20 amplifies the first signal inputted from the oscillation circuit 10 and outputs the amplified signal as the second signal. The rectifier circuit 30 rectifies the second signal inputted from the inductor 20 and outputs the rectified signal as the third signal.

The voltage stabilization circuit 40 stabilizes the voltage of the third signal and outputs the stabilized signal as the fourth signal. The charging/discharging circuit 50 inputs the fourth signal, inputted from the voltage stabilization circuit 40, to the respective gates of the first MOSFET 61 and the second MOSFET 62, thereby charging the gates. Alternatively, the charging/discharging circuit 50 inputs the fourth signal, inputted from the voltage stabilization circuit 40, to the respective gates of the first MOSFET 61 and the second MOSFET 62 to extract the charge stored in the gates, thereby discharging the gates through the fourth signal.

The inductor 20 has: the first inductor 21 that receives the first signal inputted from the oscillation circuit 10; and the second inductor 22 that outputs the second signal to the rectifier circuit 30.

In this embodiment, due to the presence of the inductor 20, the first signal is amplified at the transformation ratio corresponding to the ratio of the number of turns between the first inductor 21 and the second inductor 22. With this, even when the input signal Vin is a small signal with a small voltage value, it is possible to sufficiently amplify the fourth signal for driving the respective gates of the first MOSFET 61 and the second MOSFET 62. Thus, even when each of the first MOSFET 61 and the second MOSFET 62 has a high current-driving capacity and a high breakdown voltage, it is possible to fully drive the first MOSFET 61 and the second MOSFET 62. In addition, heat generation during switching is reduced, and a semiconductor switching element with a high breakdown voltage and a high capacity, including a compound semiconductor, can be used as the first and second semiconductor switches 61 and 62.

Moreover, the output circuit 60 is configured with the first MOSFET 61 and the second MOSFET 62, the sources of which are connected to each other. This enables signal transmission from the third terminal 3 to the fourth terminal 4 and signal transmission from the fourth terminal 4 to the third terminal 3. That is, bidirectional signal transmission is possible.

The output circuit 60 may include only one of the first MOSFET 61 or the second MOSFET 62. For example, in a case where the output circuit 60 has only the first MOSFET 61 out of these MOSFETs, the gate of the first MOSFET 61 is connected to the fifth terminal 5, and the source of the first MOSFET 61 is connected to the sixth terminal 6. In this case, when the fourth signal is inputted from the charging/discharging circuit 50 to the first MOSFET 61, the first MOSFET 61 is turned on, and signal transmission is performed from the third terminal 3 to the fourth terminal 4. When the input of the fourth signal from the charging/discharging circuit 50 is stopped, the first MOSFET 61 is turned off, and the signal transmission between the third terminal 3 and the fourth terminal 4 is blocked.

Furthermore, in this embodiment, the second signal outputted from the inductor 20 is rectified by the rectifier circuit 30 to be the third signal. The voltage of the third signal is then stabilized by the voltage stabilization circuit 40 and the stabilized signal is outputted to the charging/discharging circuit 50 as the fourth signal. Thus, the voltage value of the third signal can be stabilized by the voltage stabilization circuit 40 even when the voltage value of the second signal outputted from the inductor 20 fluctuates significantly due to the condition of a load connected to the output circuit 60, for example. In other words, the voltage value of the third signal is kept constant by the voltage stabilization circuit 40 so as not to be equal to or greater than a predetermined value. This can reduce the likelihood of either one or both of the first semiconductor switch 61 and the second semiconductor switch 62 failing due to an excessive voltage inputted to the output circuit 60. Furthermore, it is possible to stabilize the operations of the first semiconductor switch 61 and the second semiconductor switch 62. Moreover, it is possible to enhance the operational reliability of the semiconductor relay 200.

In a preferred embodiment, the functional blocks of the semiconductor relay 200 are disposed on different substrates. For example, as shown in FIG. 4A, the oscillation circuit 10 is disposed on the first substrate 151, the inductor 20 is disposed on the second substrate 152, and the rectifier circuit 30, the voltage stabilization circuit 40, and the charging/discharging circuit 50 are disposed on the third substrate 153. The first MOSFET 61 is disposed on the fourth substrate 154. The second MOSFET 62 is disposed on the fifth substrate 155.

Thus, providing the inductor 20 on the substrate different from those for the other functional blocks can prevent electromagnetic noise amplified by the inductor 20 or generated in the inductor 20 from mixing with the first to fourth signals. It is also possible to increase the isolation voltage between the input and output of the semiconductor relay 200. Furthermore, disposing the first MOSFET 61 and the second MOSFET 62 on the respective substrates different from each other, i.e., on the fourth substrate 154 and the fifth substrate 155, makes it possible to increase the withstand voltage and current capacity of the output circuit 60. The first MOSFET 61 and the second MOSFET 62 may be disposed on the substrate 1545. The substrate 1545 can be described as a substrate formed from the fourth substrate 154 and the fifth substrate 155 that are unitary with each other.

### <First Variation>

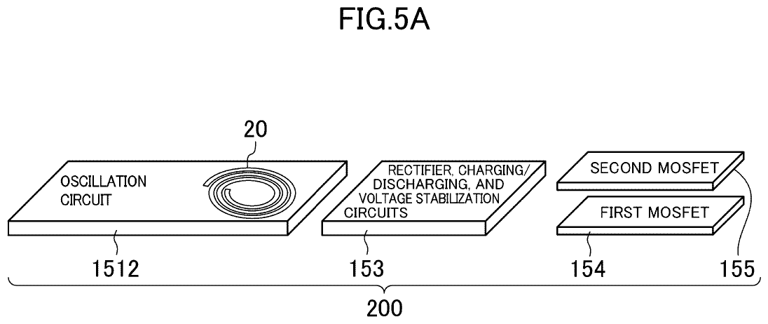

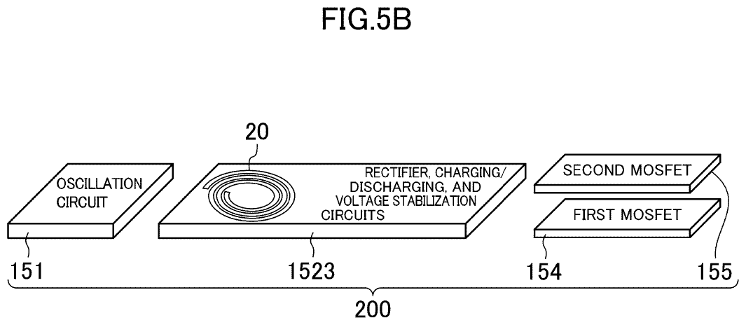

FIG. 5A is a schematic diagram showing a set of substrates that can be mounted on a semiconductor relay related to a first variation. FIG. 5B is a schematic diagram showing another set of substrates that can be mounted on the semiconductor relay related to the first variation.

For the sake of convenience in descriptions, in FIG. 5A and the subsequent figures, the same components as those described in the first embodiment are denoted by the same reference numerals, and are not described in detail.

As described in the first embodiment, disposing the functional blocks of the semiconductor relay 200 on different substrates, in particular, disposing the inductor 20 on the substrate different from those for the other functional blocks, can prevent electromagnetic noise amplified in the inductor 20 or generated in the inductor 20 from mixing with the first to fourth signals, increasing the isolation voltage between the input and output of the semiconductor relay 200.

In the examples described in the first embodiment, the second substrate 152, on which the inductor 20 is disposed, is completely separated from the first and third to fifth substrates 151 and 153 to 155, on which the other functional blocks are disposed.

However, if it is intended merely to increase the isolation voltage between the input and output of the semiconductor relay 200, the inductor 20 and the oscillation circuit 10, which is a previous-stage circuit of the inductor 20, may be disposed on a same substrate 1512, as shown in FIG. 5A. In this case, the substrate 1512 is separated from the third substrate 153, on which subsequent-stage circuits of the inductor 20 are disposed. The substrate 1512 can be described as a substrate formed from the first substrate 151 and the second substrate 152 that are unitary with each other.

Alternatively, as shown in FIG. 5B, the inductor 20 and its subsequent-stage circuits, i.e., the rectifier circuit 30, the voltage stabilization circuit 40, and the charging/discharging circuit 50, may be disposed on a same substrate 1523. In this case, the substrate 1523 is separated from the first substrate 151 where the oscillation circuit 10, which is a previous-stage circuit of the inductor 20, is disposed. The substrate 1523 can be described as a substrate formed from the second substrate 152 and the third substrate 153 that are unitary with each other.

In the examples shown in FIG. 5A and FIG. 5B, the first MOSFET 61 and the second MOSFET 62 may be disposed on the substrate 1545, as shown in FIG. 4B.

<second Variation>

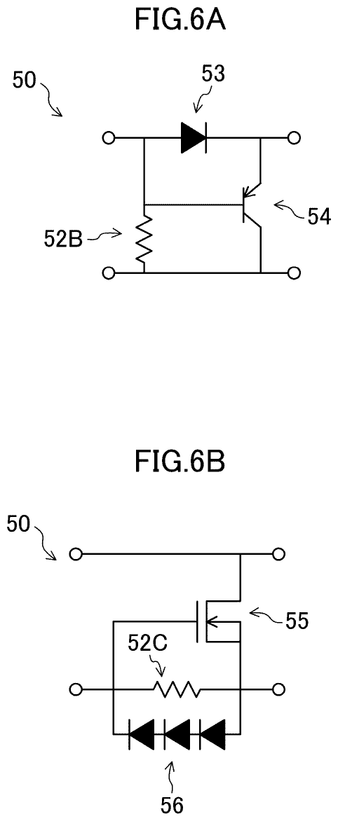

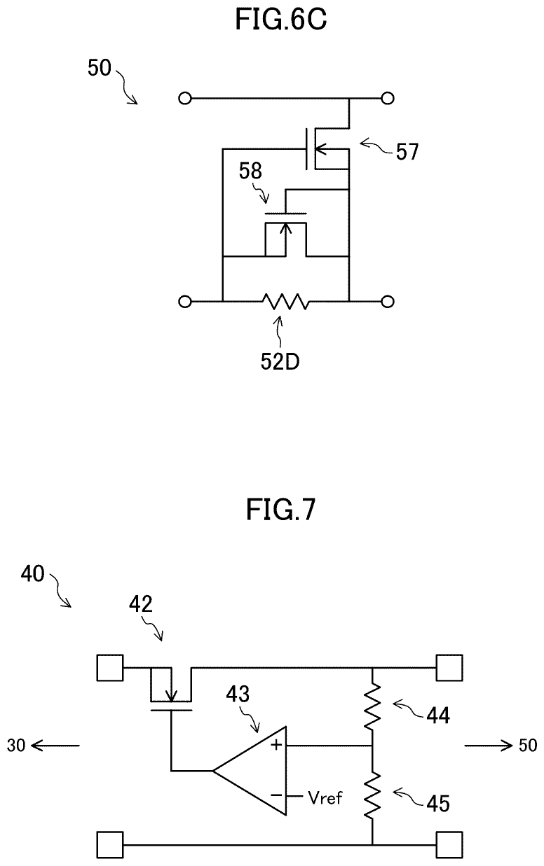

FIG. 6A is a circuit diagram of a first charging/discharging circuit related to a second variation. FIG. 6B is a circuit diagram of a second charging/discharging circuit related to the second variation. FIG. 6C is a circuit diagram of a third charging/discharging circuit related to the second variation. FIG. 7 is a circuit diagram of a voltage stabilization circuit related to the second variation.

As described above, the circuit configurations of the charging/discharging circuit 50 and the voltage stabilization circuit 40 are not limited to those in the example shown in FIG. 2.

For example, the charging/discharging circuit 50 may be configured as shown in FIGS. 6A to 6C. In the example shown in FIG. 6A, the charging/discharging circuit 50 has a PNP bipolar transistor 54, a resistor 52B, and the diode 53. The cathode of the diode 53 is connected to the emitter of the PNP bipolar transistor 54 and the anode of the diode 53 is connected to the oscillation circuit 10. The resistor 52B is connected between the base and collector of the PNP bipolar transistor 54.

In the charging/discharging circuit 50 shown in FIG. 6A, upon receiving the fourth signal inputted from the voltage stabilization circuit 40, the diode 53 is forward biased, and the emitter of the PNP bipolar transistor 54 reaches a high potential. Meanwhile, the base of the PNP bipolar transistor 54 also reaches a high potential, similar to the emitter, and therefore the PNP bipolar transistor 54 is turned off. Due to the current flowing through the diode 53, current flows between the gate and source of each of the first MOSFET 61 and the second MOSFET 62, and these gates are charged.

When the input of the fourth signal from the voltage stabilization circuit 40 is stopped, the charge stored in the gate of each of the first MOSFET 61 and the second MOSFET 62 is supplied to the base of the PNP bipolar transistor 54 via the resistor 52B, turning on the PNP bipolar transistor 54. As the PNP bipolar transistor 54 is turned on, the charge is extracted from the gate of each of the first MOSFET 61 and the second MOSFET 62 through the PNP bipolar transistor 54, and these gates are discharged. In addition, the diode 53 is reverse biased, and this prevents reverse current flow to the rectifier circuit 30.

In the example shown in FIG. 6B, the charging/discharging circuit 50 has an N-channel depletion-mode MOSFET (hereinafter, may be referred to as a D-MOSFET) 55 (hereinafter, simply referred to as D-MOSFET 55), a resistor 52C, and a diode array 56. The cathode of the diode array 56 is connected to the gate of the D-MOSFET 55 and the anode of the diode array 56 is connected to the source of the D-MOSFET 55. The resistor 52C is connected between the gate and source of the D-MOSFET 55 in parallel with the diode array 56.

In the charging/discharging circuit 50 shown in FIG. 6B, upon receiving the fourth signal inputted from the voltage stabilization circuit 40, the drain of the D-MOSFET 55 reaches a high potential. Due to this, the D-MOSFET 61 is once turned on, to allow current to flow between the drain and the source. However, once the current flows through the resistor 52C, a potential difference is generated between both ends of the resistor 52C, and the potential difference turns off the D-MOSFET 55. In this case, current flows between the gate and source of each of the first MOSFET 61 and the second MOSFET 62, and these gates are charged.

When the input of the fourth signal from the voltage stabilization circuit 40 is stopped, current no longer flows through the resistor 52C. Due to this, the D-MOSFET 55 is turned on. The charge stored in the gate of each of the first MOSFET 61 and the second MOSFET 62 is extracted from the gate via the D-MOSFET 55, the resistor 52C, and the diode array 56. The gates of the first MOSFET 61 and the second MOSFET 62 are thus discharged.

In the charging/discharging circuit 50 shown in FIG. 6C, the following changes have been made to the circuit shown in FIG. 6B: an N-channel D-MOSFET 57 (hereinafter simply referred to as D-MOSFET 57) is disposed instead of the D-MOSFET 55; and an N-channel D-MOSFET 58 (hereinafter referred to as D-MOSFET 58) is disposed instead of the diode array 56. The D-MOSFET 58 has a diode-connected configuration, where the gate and the drain are short-circuited.

The function of the D-MOSFET 57 in the charging/discharging circuit 50 shown in FIG. 6C is the same as that of the D-MOSFET 55 shown in FIG. 6B, and the function of the D-MOSFET 58 shown in FIG. 6C is the same as that of the diode array 56 shown in FIG. 6B. The function of a resistor 52D is also the same as that of the resistor 52C shown in FIG. 6B. Thus, the charging and discharging operation of the charging/discharging circuit 50 shown in FIG. 6C is similar to that of the charging/discharging circuit 50 shown in FIG. 6B, and therefore, the description thereof is omitted.

The voltage stabilization circuit 40 may be configured as shown in FIG. 7. The voltage stabilization circuit 40 shown in FIG. 7 is a so-called low-dropout regulator (LDO regulator), and has: an N-channel D-MOSFET 42 (hereinafter referred to as D-MOSFET 42); an error amplifier 43; and resistors 44 and 45. The resistors 44 and 45 are connected in series, and a connection point between the resistors is connected to the feedback terminal (plus terminal) of the error amplifier 43. A reference voltage source (with a reference voltage Vref) is connected to the reference terminal (minus terminal) of the error amplifier 43. The output terminal of the error amplifier 43 is connected to the gate of the D-MOSFET 42.

Upon receiving the third signal inputted from the rectifier circuit 30, the D-MOSFET 42 is turned on, and the fourth signal is supplied to the charging/discharging circuit 50. When the voltage value of the third signal becomes higher than a predetermined value, the feedback voltage inputted to the feedback terminal of the error amplifier 43 becomes higher than the reference voltage Vref. At this time, the output voltage of the error amplifier 43 increases in accordance with the difference between the feedback voltage and the reference voltage Vref, and therefore the on-resistance of the D-MOSFET 42 decreases. As a result, the fourth signal having a voltage value lower than that of the third signal is supplied to the charging/discharging circuit 50. This configuration prevents an excessive voltage from being applied to the charging/discharging circuit 50, and, in turn, to the output circuit 60.

### Second Embodiment

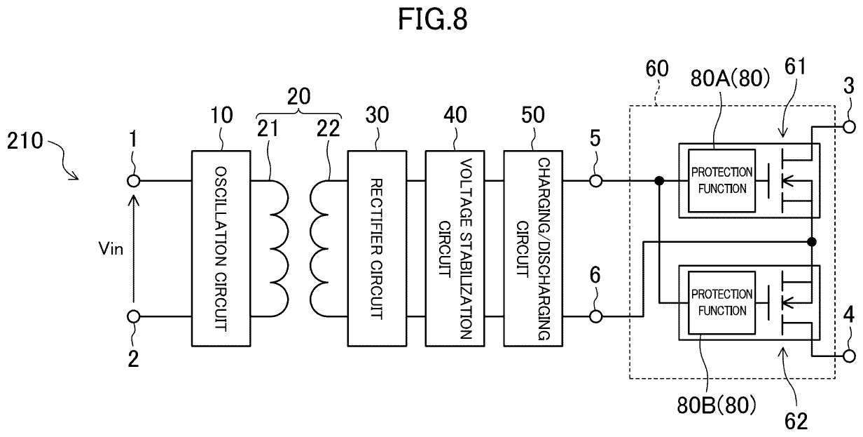

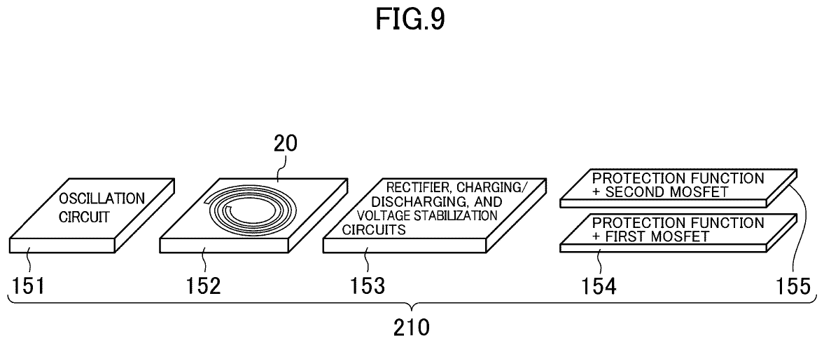

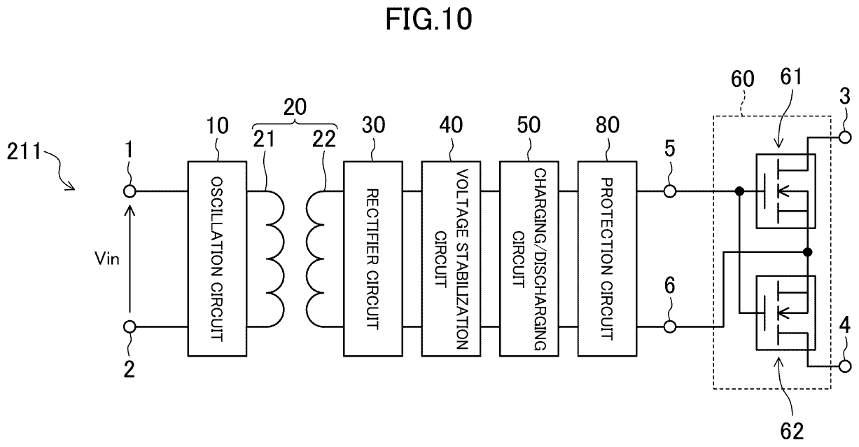

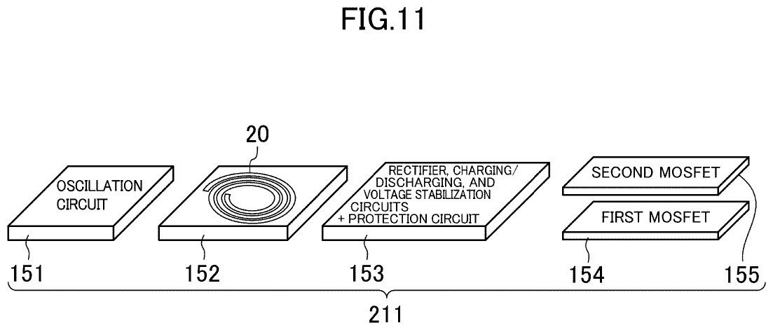

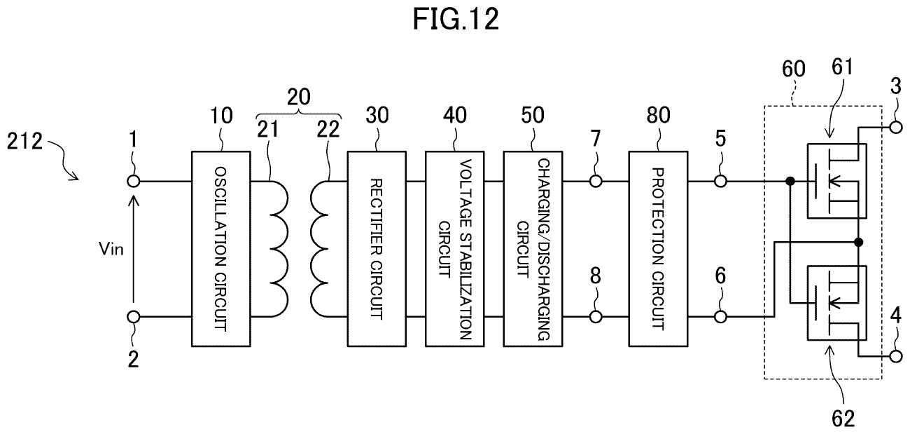

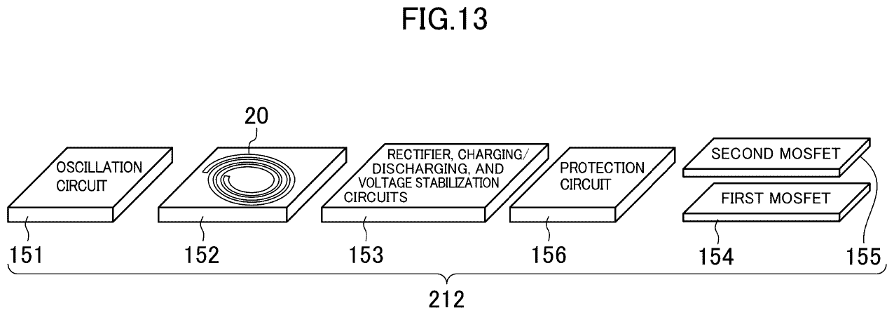

FIG. 8 is a functional block diagram of a semiconductor relay related to a second embodiment. FIG. 9 is a schematic diagram showing a set of substrates that can be mounted on the semiconductor relay. FIG. 10 is a functional block diagram of another semiconductor relay related to the second embodiment. FIG. 11 is a schematic diagram showing another set of substrates that can be mounted on the semiconductor relay. FIG. 12 is a functional block diagram of still another semiconductor relay related to the second embodiment. FIG. 13 is a schematic diagram showing still another set of substrates that can be mounted on the semiconductor relay.

Various manners and modes can be adopted to provide various protection functions for the output circuit 60. For example, as shown in FIG. 8, a semiconductor relay 210 may include protection circuits 80A and 80B provided to the first MOSFET 61 and the second MOSFET 62, respectively. In this case, as shown in FIG. 9, the first MOSFET 61 and the protection circuit 80A are on the fourth substrate 154, while the second MOSFET 62 and the protection circuit 80B are on the fifth substrate 155.

That is, in the semiconductor relay 210 shown in FIGS. 8 and 9, the protection circuit 80A for protecting the first MOSFET 61 is provided between the charging/discharging circuit 50 and the first MOSFET 61. Meanwhile, the protection circuit 80B for protecting the second MOSFET 62 is provided between the charging/discharging circuit 50 and the second MOSFET 62. As will be described later, each of the protection circuits 80A and 80B is not limited to one type, and may include multiple types of circuits. The protection circuits 80A and 80B may be collectively referred to as protection circuit 80.

The protection circuit 80 may be provided separately from the output circuit 60. For example, as shown in FIGS. 10 and 11, in a semiconductor relay 211, the protection circuit 80 may be provided on the third substrate 153, on which the rectifier circuit 30, the voltage stabilization circuit 40, and the charging/discharging circuit 50 are provided. Furthermore, as shown in FIGS. 12 and 13, a semiconductor relay 212 may further include a sixth substrate 156, and the protection circuit 80 may be on the sixth substrate 156. The sixth substrate 156 is a silicon chip, similar to the first to third substrates 151 to 153. The sixth substrate 156 is located between: the third substrate 153, on which the rectifier circuit 30, the voltage stabilization circuit 40, and the charging/discharging circuit 50 are provided; and the fourth substrate 154 and the fifth substrate 155.

In this embodiment, there is provided the protection circuit 80 having appropriate functions to deal with the fluctuation of the voltage applied to the output circuit 60, the fluctuation of the current flowing through the output circuit 60, a temperature rise in the output circuit 60 during operation, and the like, respectively. This can reduce the influences of the above-described voltage fluctuation, current fluctuation, temperature rise, and the like.

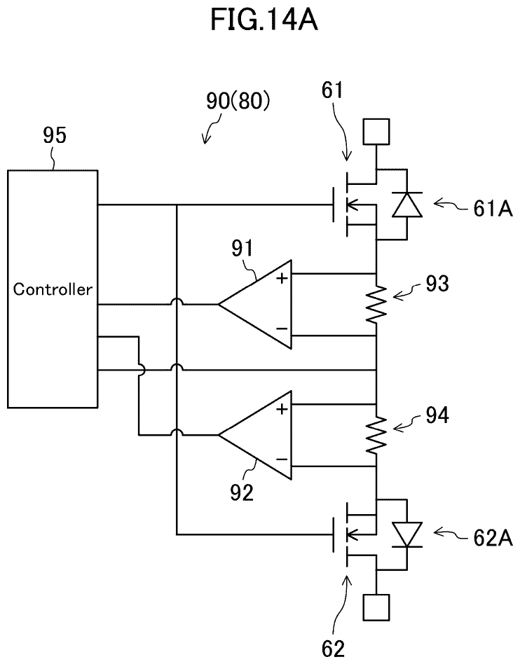

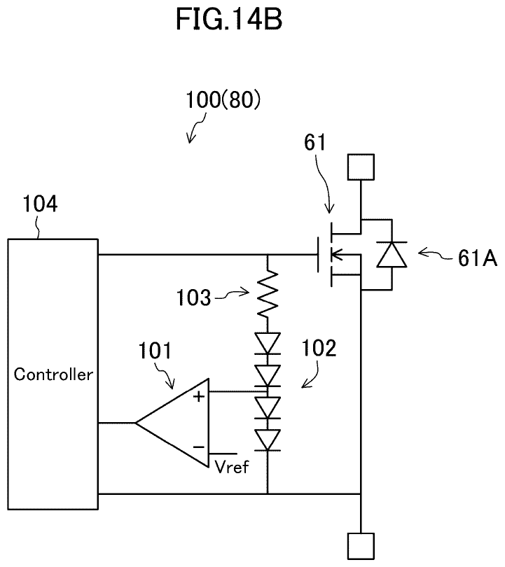

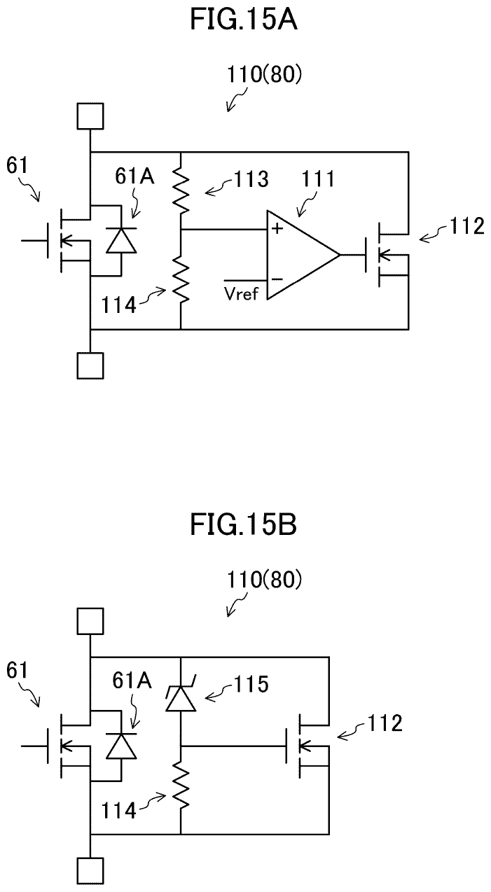

FIG. 14A is a circuit diagram of an overcurrent protection circuit. FIG. 14B is a circuit diagram of an overheat protection circuit. FIG. 15A is a circuit diagram of an overvoltage protection circuit. FIG. 15B is a circuit diagram of another overvoltage protection circuit. A diode 61A shown in FIGS. 14A to 15B and FIG. 18 is a parasitic diode (body diode) built in the first MOSFET 61, and a diode 62A shown in FIG. 14A is a parasitic diode (body diode) built in the second MOSFET 62.

An appropriate circuit is selected from the various circuits shown in FIGS. 14A to 15B, to configure the protection circuit 80. Only one type may be selected or multiple types may be selected from these circuits.

An overcurrent protection circuit 90 shown in FIG. 14A has differential amplifiers 91 and 92, sensing resistors 93 and 94, and a controller 95. The controller 95 includes one or more integrated circuits (ICs) or one or more large-scale integrations (LSIs).

The sensing resistors 93 and 94 are connected in series between the source of the first MOSFET 61 and the source of the second MOSFET 62. Two input terminals of the differential amplifier 91 are connected to both ends of the sensing resistor 93, respectively, and two input terminals of the differential amplifier 92 are connected to both ends of the sensing resistor 94, respectively.

One input terminal (minus terminal) of each of the differential amplifiers 91 and 92 is connected to a connection point between the sensing resistor 93 and the sensing resistor 94. The controller 95 has three input terminals, which are connected to the output terminal of the differential amplifier 91, the output terminal of the differential amplifier 92, and a connection point between the sensing resistor 93 and the sensing resistor 94, respectively. The controller 95 has two output terminals, which are connected to the gate of the first MOSFET 61 and the gate of the second MOSFET 62, respectively. The first MOSFET 61 and the second MOSFET 62 are driven based on an output signal from the controller 95.

When an overcurrent flows through at least one of the first MOSFET 61 or the second MOSFET 62, the potential difference between both ends of the sensing resistor 93 and the potential difference between both ends of the sensing resistor 94 both increase. The differential amplifiers 91 and 92 output, to the controller 95, signals amplified based on the potential differences, respectively. The controller 95 stops outputting signals to the gates of the first MOSFET 61 and the second MOSFET 62 based on the above signals, and turns off the first MOSFET 61 and the second MOSFET 62.

This configuration can prevent a decline in output characteristics or device failure due to overcurrent flowing through the first MOSFET 61 and the second MOSFET 62.

An overheat protection circuit 100 shown in FIG. 14B has a differential amplifier 101, a diode array 102 for temperature detection, a resistor 103, and a controller 104, and is connected to the first MOSFET 61. The controller 104 includes a plurality of ICs or one or more LSIs, similar to the controller 95. Although not shown in the figures, the overheat protection circuit 100 is also connected to the second MOSFET 62. It should be noted that another differential amplifier 101, diode array 102, and resistor 103 are provided for the second MOSFET 62, separately from those for the first MOSFET 61.

The resistor 103 and the diode array 102 are connected in series, and the anode of the diode array 102 is connected to the gate of the first MOSFET 61 via the resistor 103. An intermediate point of the diode array 102 is connected to the feedback terminal (plus terminal) of the differential amplifier 101, and the reference terminal (minus terminal) of the differential amplifier 101 is connected to a reference voltage source (with a reference voltage Vref). The gate of the first MOSFET 61, the output terminal of the differential amplifier 101, and the cathode of the diode array 102 are connected to three input terminals of the controller 104, respectively. The first MOSFET 61 is driven based on an output signal from the controller 104.

The voltage across the diode array 102 has a negative correlation to temperature. Due to this, if the temperature of the first MOSFET 61 rises during operation, the voltage across the diode array 102 drops, and the voltage inputted to the feedback terminal of the differential amplifier 101 also drops. If the temperature of the first MOSFET 61 rises to a predetermined value or higher and the voltage across the diode array 102 drops accordingly, the output of the differential amplifier 101 approaches zero. When the magnitude of the output signal from the differential amplifier 101 falls below a set value, the controller 104, having received the output signal, stops outputting a signal to the gate of the first MOSFET 61 and turns off the first MOSFET 61.

This configuration can reduce a temperature rise in the first MOSFET 61 to the predetermined value or higher, preventing a decline in output characteristics or device failure.

An overvoltage protection circuit 110 shown in FIG. 15A has a differential amplifier 111, an N-channel enhancement-mode MOSFET 112 (hereinafter, simply referred to as MOSFET 112), and resistors 113 and 114. The overvoltage protection circuit 110 is connected to the first MOSFET 61. Although not shown in the figures, another overvoltage protection circuit 110, as shown in FIG. 15A, is also connected to the second MOSFET 62. Note that the overvoltage protection circuits 110 are individually and respectively provided for the first MOSFET 61 and the second MOSFET 62.

The MOSFET 112 is connected in parallel with the first MOSFET 61. The resistors 113 and 114 connected in series are also connected in parallel with the MOSFET 112 and with the first MOSFET 61. A connection point between the resistor 113 and the resistor 114 is connected to the feedback terminal (plus terminal) of the differential amplifier 111, and the reference terminal (minus terminal) of the differential amplifier 111 is connected to a reference voltage source (with a reference voltage Vref). The output terminal of the differential amplifier 111 is connected to the gate of the MOSFET 112.

When an overvoltage is applied to the drain of the first MOSFET 61, the potential at the connection point between the resistor 113 and resistor 114 also rises accordingly, and the input voltage to the feedback terminal of the differential amplifier 111 also rises. When the input voltage exceeds a predetermined value, the output of the differential amplifier 111 increases, turning on the MOSFET 112. Furthermore, the on-resistance of the MOSFET 112 decreases. Correspondingly, the voltage applied to the drain of the first MOSFET 61 decreases.

This configuration can reduce the excessive rise in the voltage applied to the drain of the first MOSFET 61, i.e., the voltage rise to a predetermined value or higher, preventing the occurrence of failure or destruction of its devices.

Compared to the overvoltage protection circuit 110 shown in FIG. 15A, the overvoltage protection circuit 110 shown in FIG. 15B does not include the differential amplifier 111. In addition, the resistor 113 is replaced by a Zener diode 115. The anode of the Zener diode 115 is connected to the resistor 114, and the cathode of the Zener diode 115 is connected to the drains of the first MOSFET 61 and the MOSFET 112. Although not shown in the figures, another overvoltage protection circuit 110, as shown in FIG. 15B, is also connected to the second MOSFET 62. Note that the overvoltage protection circuits 110 are individually and respectively provided for the first MOSFET 61 and the second MOSFET 62.

When an overvoltage is applied to the drain of the first MOSFET 61, the reverse voltage applied to the Zener diode 115 also rises accordingly. When the reverse voltage exceeds its breakdown voltage, large current flows through the Zener diode 115, turning on the MOSFET 112. Furthermore, the on-resistance of the MOSFET 112 decreases. Correspondingly, the voltage applied to the drain of the first MOSFET 61 decreases.

This configuration can reduce the excessive rise in the voltage applied to the drain of the first MOSFET 61, i.e., the voltage rise to a predetermined value or higher, preventing the occurrence of failure or destruction of its devices.

As described above, in the semiconductor relays 210 to 212 of this embodiment, the first signal inputted from the oscillation circuit 10 undergoes signal processing such as amplification and rectification, to generate the fourth signal. That is, necessary driving power can be supplied to the protection circuit 80.

Furthermore, the protection circuit 80 can be provided on the third substrate 153, on which the voltage stabilization circuit 40 and the other circuits are provided, as shown in FIGS. 10 and 11, and this allows the protection circuit 80 to be implemented using a circuit configuration similar to those of the voltage stabilization circuit 40 and the other circuits. For example, the controller 95, 104 can be implemented using a CMOS logic circuit. This allows the protection circuit 80 to perform complicated arithmetic processing, achieving more precise operation for protecting the output circuit 60. Also in the case where the protection circuit 80 is on the dedicated sixth substrate 156, as shown in FIGS. 12 and 13, the protection circuit 80 can be implemented using a CMOS logic circuit. This allows the circuit to perform complicated arithmetic processing, achieving more precise operation for protecting the output circuit 60.

In a preferred embodiment, the overheat protection circuit 100 shown in FIG. 14B is located in the vicinity of the first MOSFET 61 and the second MOSFET 62. For example, in a preferred embodiment, the overheat protection circuit 100 is incorporated in the protection circuit 80A provided on the fourth substrate 154 and/or the protection circuit 80B provided on the fifth substrate 155, as shown in FIGS. 8 and 9.

This enables quick detection of a temperature change in the first MOSFET 61 and/or the second MOSFET 62, achieving more precise operation for protecting the output circuit 60 from overheating. Furthermore, it is possible to reduce the influence of temperature rise during operation on other circuits.

### Third Embodiment

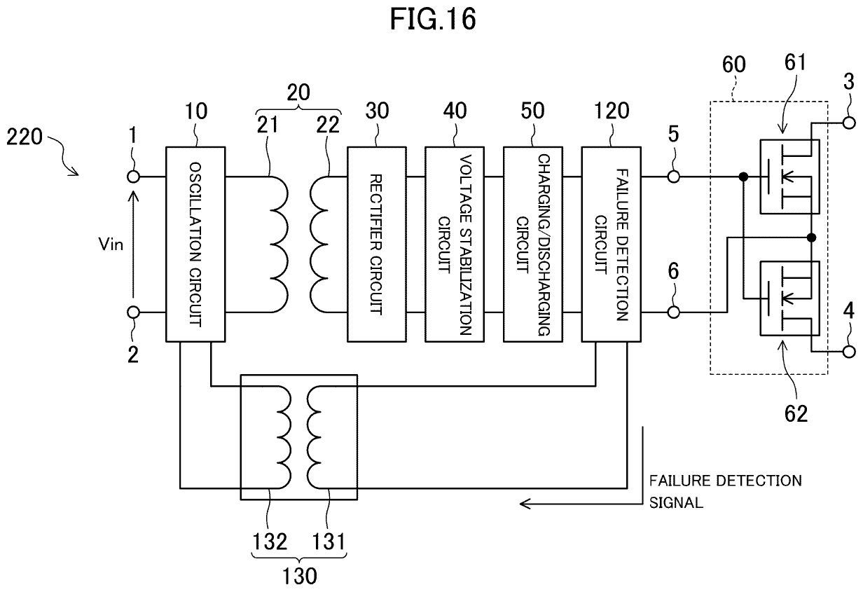

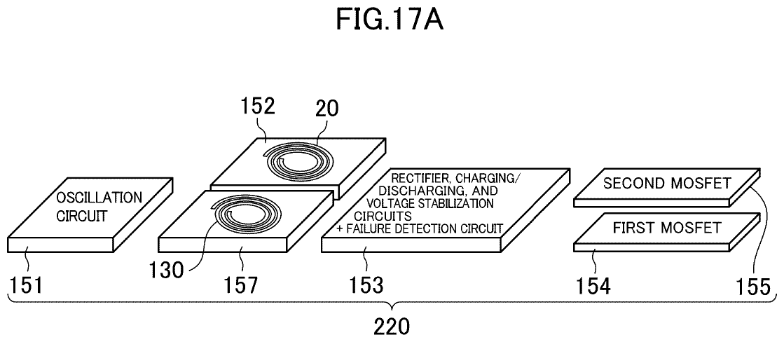

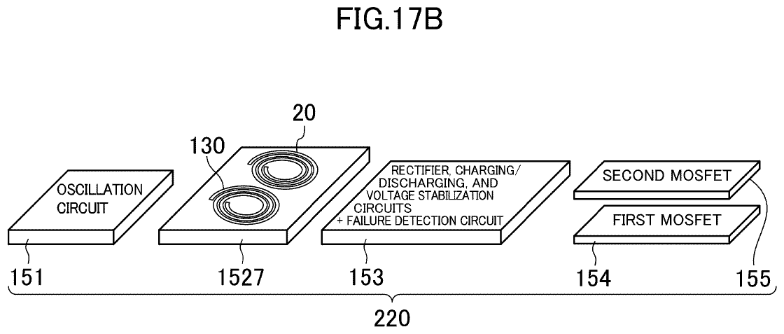

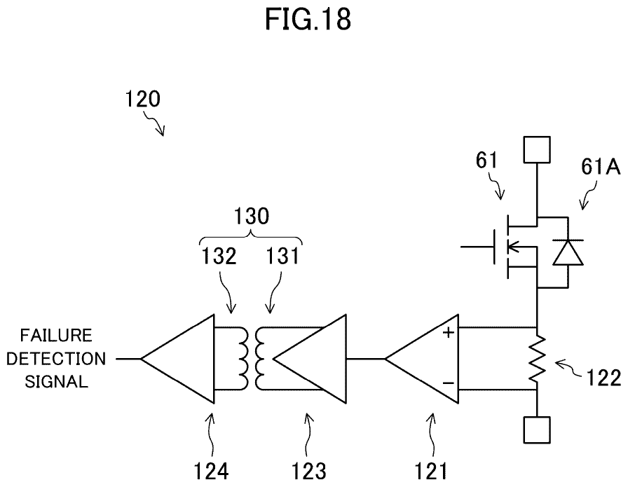

FIG. 16 is a functional block diagram of a semiconductor relay related to a third embodiment. FIG. 17A is a schematic diagram showing a set of substrates that can be mounted on the semiconductor relay. FIG. 17B is a schematic diagram showing another set of substrates that can be mounted on the semiconductor relay. FIG. 18 is a circuit diagram of a failure detection circuit.

As shown in FIG. 16, a semiconductor relay 220 of this embodiment includes a failure detection circuit 120 between the charging/discharging circuit 50 and the output circuit 60. Providing the failure detection circuit 120 makes it possible to detect, inside the semiconductor relay 220, failures of the first MOSFET 61 and the second MOSFET 62 included in the output circuit 60. In the semiconductor relay 220, the first signal inputted from the oscillation circuit 10 undergoes signal processing such as amplification and rectification, to generate the fourth signal. That is, necessary driving power can be supplied to the failure detection circuit 120.

Upon detecting a failure of the first MOSFET 61 or the second MOSFET 62, a failure detection signal is outputted from the failure detection circuit 120. The failure detection signal is inputted to a first inductor 131 of a feedback inductor 130. The failure detection signal is then modulated at a transformation ratio corresponding to the ratio of the number of turns between the first inductor 131 and a second inductor 132, and the modulated signal is fed back from the second inductor 132 to the oscillation circuit 10. Upon receiving the failure detection signal, the oscillation circuit 10 stops its operation. Alternatively, the operation of the oscillation circuit 10 may be stopped when the magnitude of the failure detection signal inputted to the oscillation circuit 10 exceeds a predetermined threshold value.

As shown in FIG. 17A, the feedback inductor 130 is provided on a seventh substrate 157. This configuration can prevent electromagnetic noise from mixing with the first to fourth signals. It is also possible to increase the isolation voltage between the input and output of the semiconductor relay 200.

As shown in FIG. 17B, the inductor 20 and the feedback inductor 130 may be provided on a same substrate 1527. Also in this case, it is possible to prevent electromagnetic noise from mixing with the first to fourth signals. It is also possible to increase the isolation voltage between the input and output of the semiconductor relay 200.

The failure detection circuit 120 includes, for example, a differential amplifier 121, a resistor 122, a driver amplifier 123, and a receiver amplifier 124, as shown in FIG. 18.

The resistor 122 is connected to the source of the first MOSFET 61, and two input terminals of the differential amplifier 121 are connected to both ends of the resistor 122, respectively. The output terminal of the differential amplifier 121 is connected to the driver amplifier 123. The driver amplifier 123 is connected to the first inductor 131 of the feedback inductor 130, and the receiver amplifier 124 is connected to the second inductor 132.

Although not shown in the figures, another failure detection circuit 120 as shown in FIG. 18 is also connected to the second MOSFET 62. Note that the failure detection circuits 120 are individually and respectively provided for the first MOSFET 61 and the second MOSFET 62.

For example, if the first MOSFET 61 fails and consequently causes a short circuit between the source and the drain, the amount of current flowing through the resistor 122 increases, and the potential difference between both ends of the resistor 122 increases. The differential amplifier 121 outputs a signal corresponding to the change in potential difference to the driver amplifier 123. Because the magnitude of the signal outputted from the driver amplifier 123 to the first inductor 131 changes, the voltage at the second inductor 132 induced as a result of magnetic coupling also changes. In response to the voltage change, the receiver amplifier 124 outputs a failure detection signal to the oscillation circuit 10.

If the first MOSFET 61 fails and consequently an open-circuit state is established between the source and the drain, the amount of current flowing through the resistor 122 decreases, and the potential difference between both ends of the resistor 122 decreases. The differential amplifier 121 outputs a signal corresponding to the change in potential difference to the driver amplifier 123. Because the magnitude of the signal outputted from the driver amplifier 123 to the first inductor 131 changes, the voltage at the second inductor 132 induced as a result of magnetic coupling also changes. In response to the voltage change, the receiver amplifier 124 outputs a failure detection signal to the oscillation circuit 10.

### Fourth Embodiment

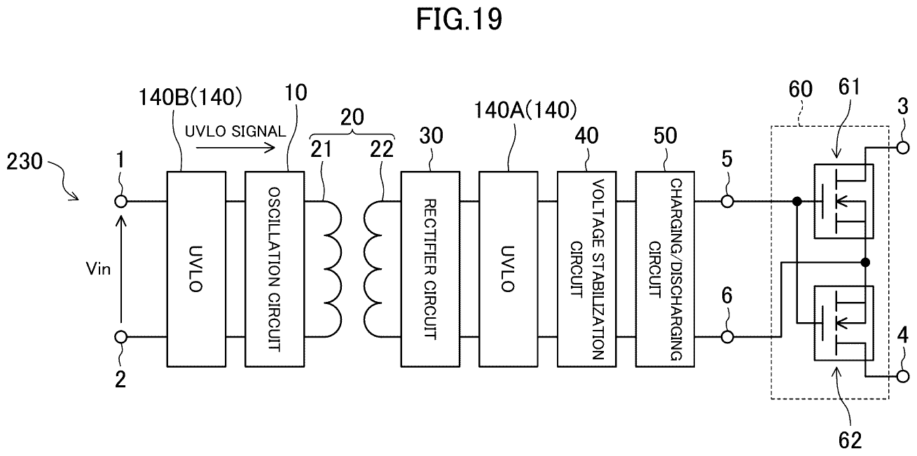

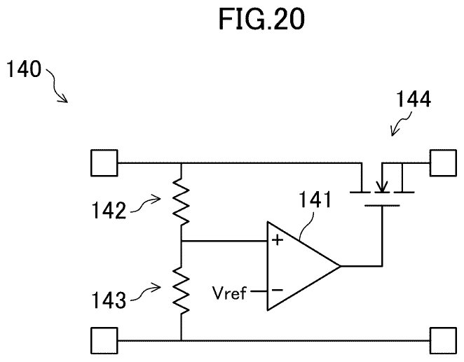

FIG. 19 is a functional block diagram of a semiconductor relay related to a fourth embodiment. FIG. 20 is a circuit diagram of an undervoltage lockout circuit.

As shown in FIG. 19, a semiconductor relay 230 of this embodiment includes a first undervoltage lockout circuit (first UVLO circuit) 140A between the rectifier circuit 30 and the voltage stabilization circuit 40. The semiconductor relay 230 further includes a second undervoltage lockout circuit (second UVLO circuit) 140B between: the first terminal 1 and the second terminal 2; and the oscillation circuit 10. The first undervoltage lockout circuit 140A and the second undervoltage lockout circuit 140B have the same circuit configuration. Thus, these circuits may be collectively referred to as undervoltage lockout circuit (UVLO circuit) 140.

Although not shown in the figures, the first undervoltage lockout circuit 140A is disposed on the third substrate 153, on which the rectifier circuit 30 and the voltage stabilization circuit 40 are disposed. The second undervoltage lockout circuit 140B is disposed on the first substrate 151, on which the oscillation circuit 10 is disposed.

As shown in FIG. 20, the undervoltage lockout circuit 140 has an operational amplifier (hereinafter referred to as an OP amplifier) 141, resistors 142 and 143, and an N-channel enhancement-mode MOSFET 144 (hereinafter, simply referred to as MOSFET 144).

The resistors 142 and 143 connected in series are connected in parallel with the rectifier circuit 30. A connection point between the resistor 142 and the resistor 143 is connected to one input terminal (plus terminal) of two input terminals of the OP amplifier 141. The other input terminal (minus terminal) of the OP amplifier 141 is connected to a reference voltage source (with a reference voltage Vref). The drain of the MOSFET 144 is connected to the rectifier circuit 30, and the source of the MOSFET 144 is connected to the voltage stabilization circuit 40. The output terminal of the OP amplifier 141 is connected to the gate of the MOSFET 144.

As the voltage value of the second signal inputted from the inductor 20 to the rectifier circuit 30 decreases, the voltage value of the third signal inputted from the rectifier circuit 30 to the first undervoltage lockout circuit 140A also decreases. In this case, the potential at the connection point between the resistor 142 and the resistor 143 decreases, and in turn, the potential at the positive terminal of the OP amplifier 141 also decreases. When the voltage value of the third signal falls below a predetermined value, the output of the OP amplifier 141 is inverted, and the MOSFET 144 is turned off. Due to this, the voltage value of the third signal outputted to the voltage stabilization circuit 40 further decreases, and the operations of the circuits subsequent to the voltage stabilization circuit 40, i.e., the operations of the charging/discharging circuit 50 and the output circuit 60 are stopped.

As described above, in this embodiment, the first undervoltage lockout circuit 140A is provided between the rectifier circuit 30 and the voltage stabilization circuit 40, and this allows the operation of the semiconductor relay 230 to be stopped when the voltage value of the second signal or the third signal falls below its predetermined value. This configuration can prevent the semiconductor relay 230 from malfunctioning.

As the voltage value of the input signal Vin decreases, the voltage value inputted to the second undervoltage lockout circuit 140B also decreases. In this case, the potential at the connection point between the resistor 142 and the resistor 143 decreases, and in turn, the potential at the positive terminal of the OP amplifier 141 also decreases. When the voltage value of the input signal Vin falls below a predetermined value, the output of the OP amplifier 141 is inverted, and the MOSFET 144 is turned off. This decreases the voltage value inputted to the oscillation circuit, and the oscillation circuit is stopped. In this way, the operation of the oscillation circuit 10 and thus the operation of the semiconductor relay 230 can be stopped, to prevent the semiconductor relay 230 from malfunctioning.

### Other Embodiments

The elements described in the first to fourth embodiments and the first and second variations may be combined as appropriate to create a new embodiment. For example, the first undervoltage lockout circuit 140A described in the fourth embodiment may be provided to the semiconductor relays 210 to 212 described in the second embodiment or to the semiconductor relay 220 described in the third embodiment. Furthermore, in each of the semiconductor relays 210 to 212, 220, and 230 described in the second to fourth embodiments, the charging/discharging circuit 50 may be any of the circuits shown in FIGS. 6A to 6C. Still further, the voltage stabilization circuit 40 may be the circuit shown in FIG. 7.

In the first to fourth embodiments, each semiconductor switch constituting the output circuit 60 is a MOSFET. However, the semiconductor switch is not particularly limited to MOSFET, and may be a metal-insulator semiconductor field-effect transistor (MISFET) or a junction field-effect transistor (JFET).

### INDUSTRIAL APPLICABILITY

The semiconductor relay of the present disclosure is capable of stabilizing the output voltage of the inductor and enhancing the operational reliability, and therefore is useful.

### DESCRIPTION OF REFERENCE CHARACTERS

1 to 6 First to Sixth Terminals
10 Oscillation Circuit
11 to 13 First to Third Inverters
14 Resistor
15 Capacitor
20 Inductor
21 First Inductor
22 Second Inductor
30 Rectifier Circuit
31 Diode
40 Voltage Stabilization Circuit
41 Zener Diode
42 N-Channel Depletion-Mode MOSFET (D-MOSFET)
43 Error Amplifier
44,45 Resistor
50 Charging/Discharging Circuit
51 NPN Bipolar Transistor
52A to 52D Resistors
53 Diode
54 PNP Bipolar Transistor
55 N-Channel Depletion-Mode MOSFET (D-MOSFET)
56 Diode Array
57,58 N-Channel Depletion-Mode MOSFET (D-MOSFET)
60 Output Circuit
61 First MOSFET (First Semiconductor Switch)
61A Parasitic Diode
62 Second MOSFET (Second Semiconductor Switch)
62A Parasitic Diode
70 Substrate
70a n⁻ Region
70b n⁺ Region
71 p⁻ Type Well
72 n⁺ Region
73 Gate Oxide Film
74 Gate Electrode
75 Source Electrode
76 Drain Electrode
80 Protection Circuit
80A, 80B Protection Circuit
90 Overcurrent Protection Circuit
91, 92 Differential Amplifier
93,94 Sensing Resistor
95 Controller
100 Overheat Protection Circuit
101 Differential Amplifier
102 Diode Array
103 Resistor
104 Controller
110 Overvoltage Protection Circuit
111 Differential Amplifier
112 N-Channel Enhancement-Mode MOSFET
113, 114 Resistor
115 Zener Diode
120 Failure Detection Circuit
121 Differential Amplifier
122 Resistor
123 Driver Amplifier
124 Receiver Amplifier
130 Feedback Inductor
131 First Inductor
132 Second Inductor
140 Undervoltage Lockout Circuit (UVLO Circuit)
140A First Undervoltage Lockout Circuit
140B Second Undervoltage Lockout Circuit
141 Operational Amplifier
142, 143 Resistor
144 N-Channel Enhancement-Mode MOSFET
151 to 157 First to Seventh Substrates
1512 Substrate
1523 Substrate
1527 Substrate
1545 Substrate
200 Semiconductor Relay
210 to 212 Semiconductor Relays
220 Semiconductor Relay
230 Semiconductor Relay

1. A semiconductor relay comprising:
an oscillation circuit configured to output a first signal;
an inductor configured to amplify the first signal inputted from the oscillation circuit and output the amplified signal as a second signal;
a rectifier circuit configured to rectify the second signal inputted from the inductor and output the rectified signal as a third signal;
a voltage stabilization circuit configured to stabilize a voltage of the third signal and output the stabilized signal as a fourth signal;
a first MOSFET configured to receive the fourth signal inputted thereto; and
a charging/discharging circuit configured to charge a gate of the first MOSFET with the fourth signal outputted from the voltage stabilization circuit or to discharge the gate of the first MOSFET through the fourth signal,
the inductor including: a first inductor configured to receive the first signal inputted from the oscillation circuit; and a second inductor configured to output the second signal to the rectifier circuit.

2. The semiconductor relay of claim 1, wherein
the oscillation circuit is disposed on a first substrate,
the inductor is disposed on a second substrate,
the rectifier circuit, the voltage stabilization circuit, and the charging/discharging circuit are disposed on a third substrate, and
the first MOSFET is disposed on a fourth substrate.

3. The semiconductor relay of claim 2, wherein
the first substrate and the second substrate are unitary with each other.

4. The semiconductor relay of claim 2, wherein
the second substrate and the third substrate are unitary with each other.

5. The semiconductor relay of claim 2, further comprising
a second MOSFET configured to receive the fourth signal inputted thereto, wherein
the charging/discharging circuit is configured to charge a gate of the second MOSFET with the fourth signal outputted from the voltage stabilization circuit or to discharge the gate of the second MOSFET through the fourth signal.

6. The semiconductor relay of claim 5, wherein
the second MOSFET is disposed on a fifth substrate.

7. The semiconductor relay of claim 6, wherein
the fourth substrate and the fifth substrate are unitary with each other.

8. The semiconductor relay of claim 2, further comprising:
at least one protection circuit between the charging/discharging circuit and the first MOSFET, the protection circuit being configured to protect the first MOSFET.

9. The semiconductor relay of claim 8, wherein
the at least one protection circuit is a single protection circuit or a plurality of protection circuits provided between the charging/discharging circuit and the first MOSFET,
the at least one protection circuit includes at least one of an overcurrent protection circuit, an overvoltage protection circuit, or an overheat protection circuit, and
the at least one protection circuit is disposed on the third substrate or the fourth substrate.

10. The semiconductor relay of claim 8, further comprising
a sixth substrate, wherein
the at least one protection circuit is a single protection circuit or a plurality of protection circuits provided between the charging/discharging circuit and the first MOSFET,
the at least one protection circuit includes at least one of an overcurrent protection circuit, an overvoltage protection circuit, or an overheat protection circuit, and
the at least one protection circuit is disposed on the sixth substrate.

11. The semiconductor relay of claim 9, wherein the at least one protection circuit disposed on the fourth substrate is the overheat protection circuit.

12. The semiconductor relay of claim 2, further comprising:
a failure detection circuit configured to detect a failure of the first MOSFET;
a feedback inductor; and
a seventh substrate, wherein
the failure detection circuit is further disposed on the third substrate,
the feedback inductor is disposed on the seventh substrate, and
a failure detection signal outputted from the failure detection circuit is inputted to the oscillation circuit via the feedback inductor.

13. The semiconductor relay of claim 12, wherein
the second substrate and the seventh substrate are unitary with each other.

14. The semiconductor relay of claim 2, further comprising
a first undervoltage lockout circuit (first UVLO circuit), wherein
the first undervoltage lockout circuit is located between the rectifier circuit and the voltage stabilization circuit and is disposed on the third substrate.

15. The semiconductor relay of claim 1, further comprising
a second undervoltage lockout circuit (second UVLO circuit), wherein
the second undervoltage lockout circuit is configured to input an undervoltage lockout signal to the oscillation circuit.

16. The semiconductor relay of claim 1, wherein
the first MOSFET has a gate terminal on a first surface of the first MOSFET and has a drain terminal on a second surface opposite to the first surface.

17. The semiconductor relay of claim 1, wherein
the first MOSFET has a gate terminal, a source terminal, and a drain terminal on a first surface of the first MOSFET.
